(19) United States
(12) Patent Application Publication
(10) Pub. No.: US 2023/0112884 A1
(43) Pub. Date: Apr. 13, 2023

(54) MODULAR TRAY FOR SOLID CHEMICAL VAPORIZING CHAMBER

(71) Applicant: ENTEGRIS, INC., Billerica, MA (US)

(72) Inventors: Scott L. Battle, Cedar Park, TX (US); Jacob Thomas, Leander, TX (US); Benjamin H. Olson, Florence, TX (US); John N. Gregg, Marble Falls, TX (US)

(21) Appl. No.: 17/961,470

(22) Filed: Oct. 6, 2022

Related U.S. Application Data
(60) Provisional application No. 63/253,798, filed on Oct. 8, 2021.

(51) Int. Cl. C23C 16/448; C23C 16/455

(52) U.S. Cl. CPC C23C 16/448; C23C 16/45544

(57) ABSTRACT

A modular tray for an ampoule of a delivery system of solid precursor materials used in Atomic Layer Deposition (ALD) processes, Chemical Vapor Deposition (CVD) processes or both. The modular tray is configured with separate components which can enhance the ease of which the modular tray can be inserted into the ampoule, and the tray is configured to make improved contact with inner wall surfaces of the ampoule to provide improved heat transfer from the inner wall to the modular tray and ultimately to the solid precursor materials disposed on the modular tray.

### PRIORITY

This disclosure claims priority to U.S. Provisional Patent No. 63/253,798, with a filing date of Oct. 8, 2021. The priority document is incorporated by reference for all purposes.

### FIELD

This disclosure relates generally to delivery systems of solid precursor materials used in Atomic Layer Deposition (ALD) processes, Chemical Vapor Deposition (CVD) processes or both.

### BACKGROUND

A delivery system designed for transport of solid precursor materials used in ALD and CVD processes are used in manufacturing processes of wafers. Such systems can include ampoules configured to contain solid precursor materials.

### SUMMARY

Some embodiments of a delivery system include an ampoule having a body which defines an interior chamber with inner surface(s). At least some of these embodiments of the delivery system are used in ALD, CVD, or both processes. Solid precursor materials can be used in fabrication of microelectronic devices. In some embodiments, the solid precursor materials are a variety of organic precursors, inorganic precursors, metal organic precursors, or combination(s) thereof. In some embodiments, heat is required to use the solid precursor materials.

In some embodiments, the ampoule includes, in its inner chamber, at least one tray for holding the solid precursor materials. In some embodiments, the trays are configured with passageways for flowing a fluid, such as a carrier gas, from bottom of the inner chamber to the top of the inner chamber, from the top of the inner chamber to the bottom of the inner chamber, or both.

In some embodiments, the tray is configured to conduct heat from the inner surface(s) of the interior chamber to the solid precursor materials. In some embodiments, the tray is configured with at least a portion to push a part of the tray to increase or maximize the contact with the inner surface(s) of the interior chamber. In some embodiments, the tray is configured with a portion that increases or maximizes the heat transfer from the inner surface(s) of the interior chamber to another part of the tray, the solid precursor materials, or both.

In some embodiments, the tray is modular. That is, the tray is formed of separate modular components. The modular components are configured to interconnect together to form the tray. Thus, each modular component(s) can be placed in the inner chamber of the ampoule with ease or relative ease. Further, each module component(s) can be taken out of the inner chamber of the ampoule with ease or relative ease. When placed within the inner chamber, the modular components can be configured to complete the formation of the tray (e.g., change its structure) to be secured and held fast within the inner chamber. According to some embodiments, the tray can have portion(s) that engage, contact, connect to, or any combination thereof, to the inner surface or other parts of the inner chamber in a mechanical way, frictional way, or both.

In some embodiments, a modular tray comprises a first component; a second component; and a third component, wherein the first component, the second component, and the third component are configured to be disengageably connectable together, such that when connected together, the second component is in thermal contact with the first component, and the third component is in thermal contact with the first component and the second component.

In some embodiments of the modular tray, the first component includes a top plate; the second component includes a wedge; and the third component includes a bottom plate, wherein the second component is disposed between the first component and the third component.

In some embodiments, the modular tray comprises a bottom plate, wherein the bottom plate is configured to hold solid precursor materials, wherein the bottom plate is configured to be disengageably connectable to at least one of the first component, the second component, or the third component, such that when connected, the bottom plate is in thermal contact with at least one of the first component, the second component, or the third component.

In some embodiments of the modular tray, the first component includes a first wall having a first arced portion; the second component includes a second wall having a second arced portion; and the third component includes a wedge portion, wherein the wedge portion is configured to be disengageably connect to the first arced portion to define a first divided compartment.

In some embodiments of the modular tray, the wedge portion is configured to push the first arced portion towards an inner wall surface of the ampoule for enhancing a thermal energy transfer from the inner wall surface to the solid precursor materials.

In some embodiments of the modular tray, the wedge portion is configured to be disengageably connect to the second arced portion to define a second divided compartment.

In some embodiments of the modular tray, the wedge portion is configured to push the second arced portion towards an inner wall surface of the ampoule for enhancing a thermal energy transfer from the inner wall surface to the solid precursor materials.

In some embodiments of the modular tray, the first component comprises a bottom plate portion; and an arced wall portion, wherein the bottom plate portion is configured to be in thermal contact with the arced wall portion.

In some embodiments of the modular tray, the first component comprises a first wall portion, wherein the first wall portion is in thermal contact with the bottom plate portion and the arced wall portion; and a second wall portion, wherein the second wall portion is in thermal contact with the bottom plate portion, the arced wall portion, and the first wall portion.

In some embodiments of the modular tray, the first component defines a first divided compartment.

In some embodiments of the modular tray, the second component defines a second divided compartment.

In some embodiments of the modular tray, the third component defines a third divided compartment.

In some embodiments, the modular tray comprises a fourth component, wherein the fourth component defines a fourth divided compartment, wherein the fourth component is configured to be disengageably connect to at least one of the first compartment, the second component, the third component, or any thereof, such that when connected, the fourth component is in thermal contact with at least one of the first component, the second component, the third component, or any thereof.

In some embodiments of the modular tray, any one or more of the first component, the second component, the third component, or the fourth component have substantially similar structures.

In some embodiments of the modular tray, the first component and the second component connect together to define a flow path for a carrier gas.

In some embodiments of the modular tray, the second component and the third component connect together to define a flow path for a carrier gas.

In some embodiments of the modular tray, the third component and the fourth component connect together to define a flow path for a carrier gas.

In some embodiments, an ampoule comprises the modular tray according to any of the tray embodiments described herein.

In some embodiments, a method of inserting a modular tray into an ampoule comprises obtaining the modular tray according to any of the embodiments described herein, the method comprises inserting the first component into an inner volume of the ampoule; inserting the second component into the inner volume of the ampoule; inserting the third component into the inner volume of the ampoule; and connecting together the first component, the second component, and the third component.

In some embodiments, the method of inserting a modular tray into an ampoule further comprises inserting the fourth component into the inner volume of the ampoule; and connecting the fourth component with the first component, the second component, and the third component.

### BRIEF DESCRIPTION OF THE DRAWINGS

References are made to the accompanying drawings that form a part of this disclosure and that illustrate embodiments in which the systems and methods described in this Specification can be practiced. Like reference numbers represent the same or similar parts throughout.

FIG. 1 shows a schematic cross-sectional view of an ampoule containing trays according to some of the embodiments.

FIG. 2A shows a modular tray according to some of the embodiments.

FIGS. 2B and 2C each show a component of the modular tray shown in FIG. 2A.

FIG. 3A shows a modular tray according to some of the embodiments.

FIG. 3B shows an exploded view of the modular tray shown in FIG. 3A.

FIG. 4A shows a modular tray according to some of the embodiments.

FIG. 4B shows one of the components of the modular tray shown in FIG. 4A.

FIG. 5 shows a modular tray according to some of the embodiments.

FIG. 6 shows a flowchart according to some of the embodiments of the methods for inserting a modular tray into an ampoule.

FIG. 7 shows a flowchart according to some of the embodiments of the methods for inserting a modular tray into an ampoule.

FIG. 8 shows a flowchart according to some of the embodiments of the methods for inserting a modular tray into an ampoule.

### DETAILED DESCRIPTION

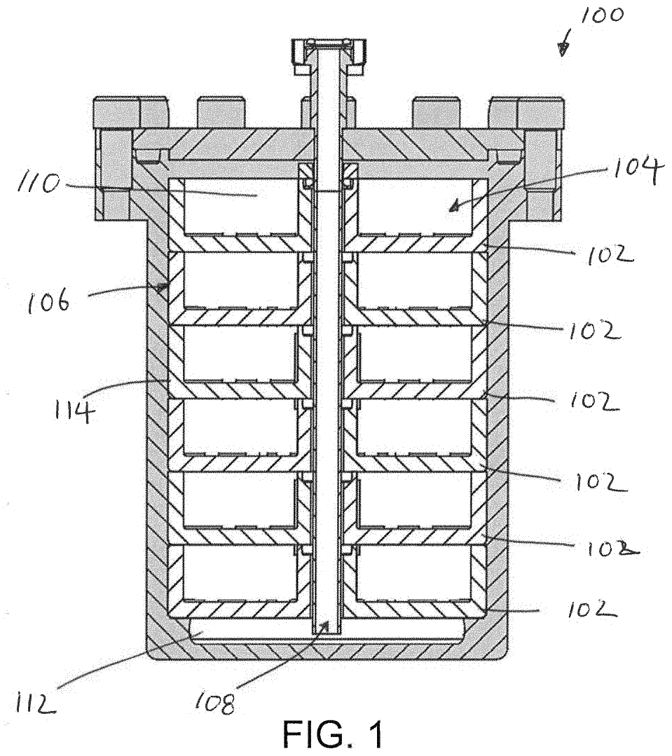

FIG. 1 shows a schematic cross-sectional view of an exemplary ampoule 100 according to some embodiments. The ampoule 100 contain trays 102 according to any of the embodiments described herein in any combination. The ampoule 100 has an inner chamber 104 which defines an inner volume sufficient for holding a stack of trays 102 and also allow for flow of a fluid (e.g., gas) within the inner volume. As shown in FIG. 1, the inner chamber 104 and its volume is generally cylindrical in shape.

The inner chamber 104 has an inner wall surface 106. Each of the trays 102 is configured to be stackable and sized to be contained within the inner volume of the inner chamber 104. The inner chamber 104 includes flow path(s) 108 for flowing a fluid (e.g., gas) upwards towards the top 110 of the inner chamber 104, downwards towards the bottom 112 of the inner chamber 104, or both. The trays 102 are also each configured to allow the flow of fluid upwards, downwards, or both. For example, each of the trays 102 can have perforations or holes through the body of the tray 102.

Each tray 102 has a portion 114 configured to be in contract with the inner wall surface 106. Increasing the area of surface-to-surface contact of the portion 114 with the inner wall surface 106 enhances heat transfer from the inner wall surface 106 to the tray 102, and thus, enhances heat transfer to the solid precursor materials. The tray 102 may be stainless steel, graphite, aluminum, or other material suitable for the use in the ampoule. The tray 102 may include a coating to protect the tray during use, for example, ceramic coatings such as aluminum oxide or polymeric coatings such as PTFE.

Because the diameter of the inner chamber 104 generally does not change, the tray 102 which can be disassembled to separate modular components can make the process of inserting the trays and stacking them in the inner chamber 104 relatively easy. The embodiments of the trays 102 disclosed herein can achieve both advantages of being able to be inserted easily into the inner chamber 104 of the ampoule 100, and then assembled together such that the formed trays 102 make improved contact with the inner wall surface 106 of the ampoule 100 to provide good heat transfer from the inner wall surface 106 to the tray 102 and/or the solid precursor materials disposed on the tray 102. Various exemplary embodiments of the trays 102 are described below.

The term “modular” as used herein means a device which can be disassembled to separate components, and be able to be put together to form said device.

The term “compressible” as used herein means a configuration of a structure, a material, or both, that is designed to be able to alter, change, shorten, lengthen, or any combination thereof, a device or a portion of a device's linear length, radial length, diametric length, circumferential length, or any combination thereof. Examples of a compressible structure includes one or more of a spring, accordion-like structure, open-ring, mechanical joints with or without a locking mechanism(s), malleable material, porous material, etc.

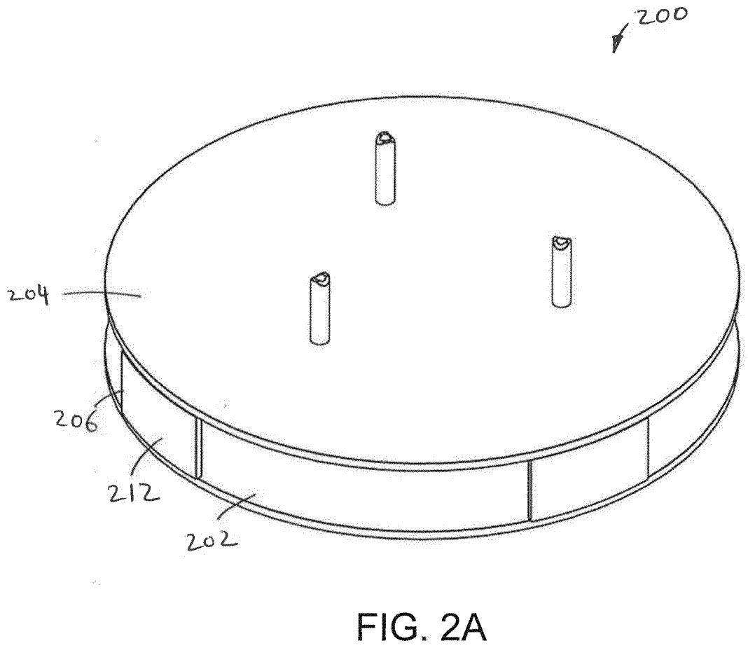

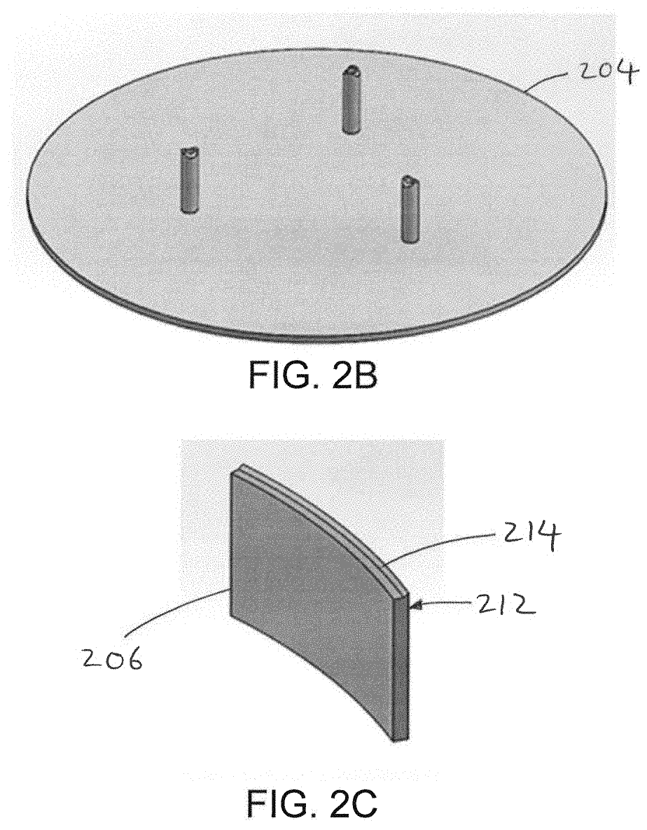

FIG. 2A shows an assembled modular tray 200 according to some of the embodiments. The modular tray 200 is configured to stack with other same or similar trays. The tray 200 includes at least three separable components, a lower plate 202, an upper plate 204, and at least one wedge piece 206. FIG. 2B shows an embodiment of the lower plate 202. In some embodiments, the upper plate 204 has the same structure as the lower plate 202. One or both of the lower plate 202 or the upper plate 204 is(are) configured to hold solid precursor materials. FIG. 2C shows an embodiment of the at least one wedge piece 206. In some embodiments, at least some or all of the components of the modular tray 200 are configured to transfer heat from one or more of the components to another component(s). In some embodiments, at least some or all of the components of the modular tray 200 are made of a material which allows for the transfer of heat from one or more of the components to another component(s). When assembled, as shown in FIG. 2A, the lower plate 202 is at the bottom forming the bottom of the tray to hold the solid precursor material, the at least one wedge piece 206 is placed at the perimeter or periphery of the lower plate 202, and then the upper plate 204 is placed on top forming the top of the tray, connecting to the at least one wedge piece 206. In some embodiments, the wedge piece(s) 206 is(are) sandwiched between the lower plate 202 and the upper plate 204. The outer periphery surfaces 208, 210 of the lower plate 202 and the upper plate 204 can be in contact with the inner wall surface of the ampoule. The wedge piece 206 has a curved outer surface 212 which is configured to contact the inner wall surface(s) of the ampoule. In some embodiments, the top surface 214 of the wedge piece 206 can have a configuration which includes a slope or a step, such that when assembled together and the upper plate 204 of the tray 200 is pushed downward, this downward force can press the top surface 214 of the wedge piece 206 to push the curved surface(s) 212 away from each other such that wedge piece(s) 206 enhances its contact with an inner wall surface of the ampoule. The upper plate 204 is now positioned to hold solid precursor material, and have additional wedge pieces 212 placed on it as it becomes the bottom plate for subsequent trays to stack upon, until the ampoule inner volume is filled.

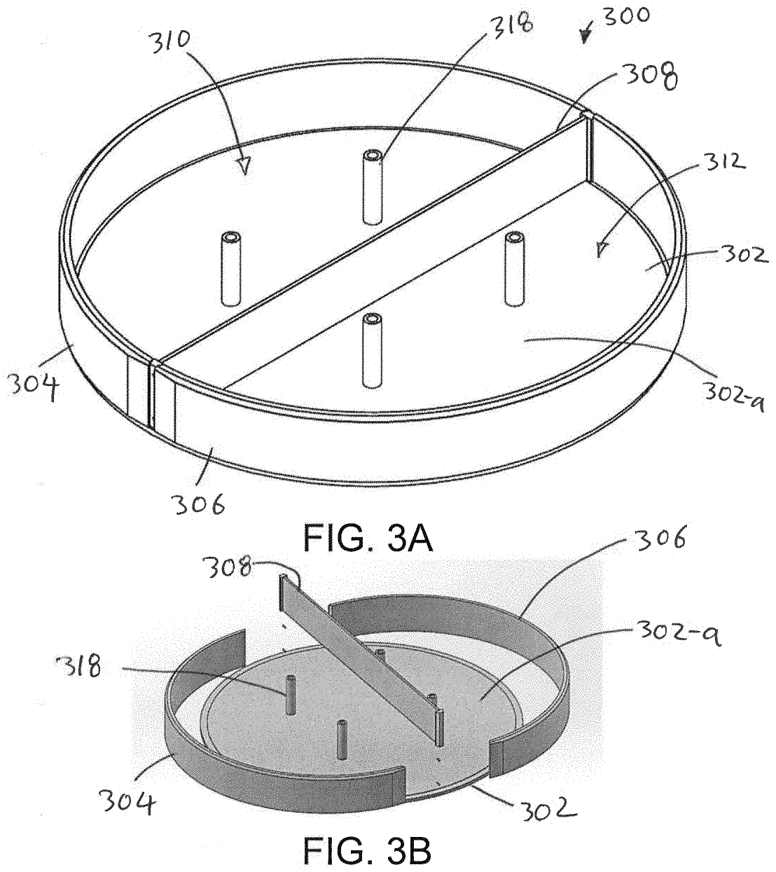

FIGS. 3A and 3B show various views of a tray 300 according to some of the embodiments. FIG. 3A shows a perspective view of the tray 300. FIG. 3B shows an exploded view of the tray 300. The tray 300 is not a single unitary structure. The tray 300 is a modular structure which is assembled from at least four separate components 302, 304, 306, 308. The resulting assembled tray 300 has two compartments 310, 312 for holding solid precursor materials.

The four components 302, 304, 306, 308 of the tray 300 are a base plate 302 which has a surface 302-a for holding the solid precursor materials; a first arced wall component 304; a second arced wall component 306; and a wedge component 308. The two arced wall components 304, 306 are configured to connect at the peripheral or perimeter of the base plate 302 as shown in FIG. 3A. The wedge component 308 connects to the ends of the two arced wall components 304, 306, and the insertion and connection of the wedge component 308 causes the two arced wall components 304, 306 to push away from each other, along a diametrically opposing direction (e.g., outward away from the wedge component 308. When the tray 300 is inside an ampoule, this “pushing away” of the arced wall components 304, 306 enhances the surface-to-surface contact between the inner surface wall(s) of the ampoule and the outer surfaces 314, 316 of the arced wall components 304, 306. This increased surface-to-surface contact increases the transfer of heat from the inner wall surface(s) of the ampoule to the two arced wall components 304, 306, which in turn enhances the thermal heat transfer from the two arced wall components 304, 306 to the base plate 302. Further, the wedge component 308 provides an additional surface area to increase heat transfer from the tray 300 to the solid precursor materials on the surface(s) 302-a of the tray 300.

The tray 300 also has at least one passageway(s) 318 for fluid flow (e.g., flow of gas) when the tray 300 is installed within an ampoule. The tray 300 is also configured to be stackable with other trays of same or similar structure.

The modular tray 300 can be placed in and taken out of the ampoule with greater ease because the module tray 300 can be assembled or disassembled with relative ease.

In some embodiments, the surface 302-a of the base plate 302 for holding the solid precursor materials is planar. In some embodiments, the surface 302-a is non-planar. In some embodiments, the surface 302-a includes planar portions and non-planar portions.

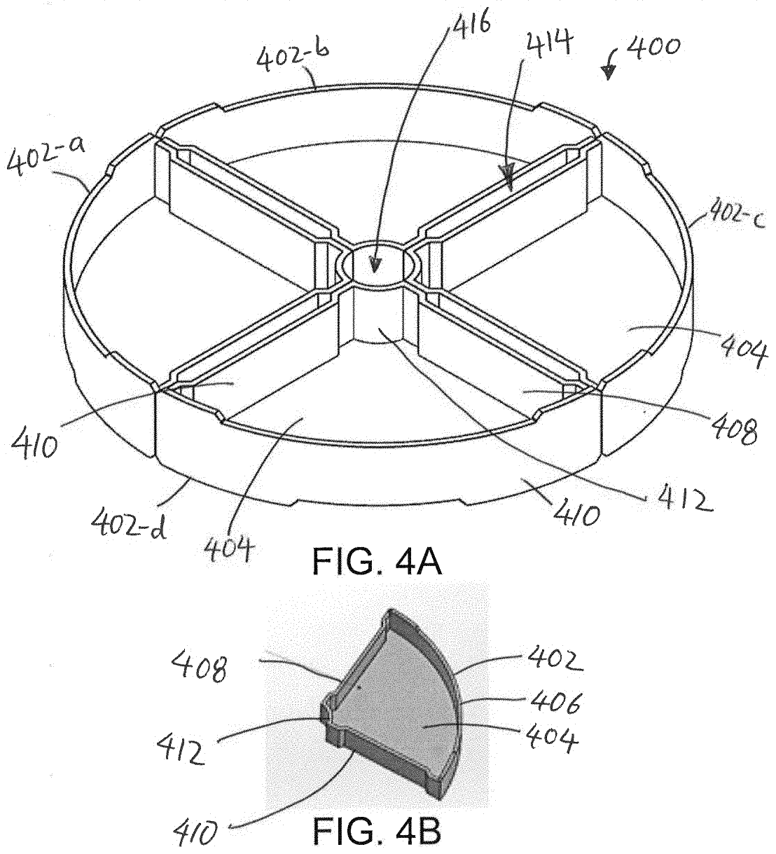

FIG. 4A shows a modular tray 400 according to some of the embodiments. FIG. 4B shows one of the components 402 of the tray 400. The modular tray 400 has four components 402-a, 402-b, 402-c, 402-d that connect together to form the completely assembled modular tray 400. Each component 402 has a base 404, an arced outer wall 406, a first radial wall 408, a second radial wall 410, and an arced inner wall 412. The two radial walls 408, 410 are configured to contact and/or connect to a respective radial wall of another component. The two radial walls 408, 410 are configured with a structure for forming a vent 414 for allowing fluid to flow therethrough. The arced inner wall 412 is also configured to form a vent 416 when the modular tray 400 is assembled, and this vent 416 allows fluid to flow therethrough. The base 404 is configured to hold solid precursor materials. The modular tray 400, when assembled inside the inner chamber of an ampoule, exerts an outwardly radial pressure such that the arced outer walls 406 of each of the components 402-a, 402-b, 402-c, 402-d increases the surface-to-surface contact of the arced outer walls 406 with the inner wall surface(s) of the inner chamber of the ampoule.

This increased surface-to-surface contact increases the transfer of heat from the inner wall surface(s) of the ampoule to the arced outer walls 406, which in turn enhances the thermal heat transfer to the base 404. Further, the radial walls 408, 410 provide additional surface areas to increase heat transfer from the tray 400 to the solid precursor materials on the surface(s) of the tray 400. The tray 400 is also configured to be stackable with other trays of same or similar structure. The modular tray 400 can be placed in and taken out of the ampoule with greater ease because the module tray 400 can be assembled or disassembled with relative ease. In some embodiments, the surface(s) of the base 404 is planar. In some embodiments, the surface(s) of the base 404 is non-planar. In some embodiments, the surface(s) of the base 404 includes planar portions and non-planar portions.

Although not shown, the tray 400 can include another component that can be a wedge configured to be placed in the center vent of the tray 400. The wedge can provide an additional outward force along the radial directions to enhance the pushing of the modular components 402 outward towards the ampoule's inner wall surface(s).

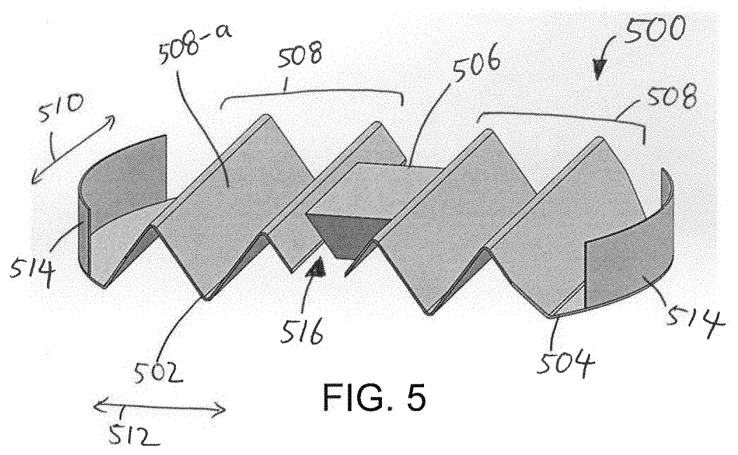

FIG. 5 shows a modular tray 500 according to some of the embodiments. The modular tray 500 is not a single unitary structure. The modular tray 500 includes at least three components 502, 504, 506. Each of the first two components 502, 504 has an accordion-like structure 508, wherein the accordion-like structure 508 has a ridge direction 510 and a fold direction 512. The accordion-like structure 508 includes an accordion-like surface 508-a. In some embodiments, the surface 508-a is planar. In some embodiments, the surface 508-a is non-planar. In some embodiments, the surface 508-a includes planar portions and non-planar portions. The accordion-like structure 508 is compressible along the fold direction 512, but not along the ridge direction 510. When the accordion-like structure 508 is compressed, the spring potential energy is increased. That is, the spring potential energy of the accordion-like structure 508 in the compressed state is higher than its relaxed state. The maximums and minimums of the accordion-like structure 508 is configured to have at least one surface for holding solid precursor materials. Further, the accordion-like structure 508 has a higher surface area to increase heat transfer from the tray to the solid precursor materials on the surface(s) of the tray 500. Each of the components 502, 504 includes an arced surface area portion 514 at an end of and along the fold direction 512. The arced surface area portion 514 is curved and configured to contact an inner wall surface(s) of the inner chamber of the ampoule. The two components 502, 504 are configured to be placed such that their fold directions 512 are aligned, such that the third component 506 can be disposed between the two components 502, 504. The third component 506 is configured to be a wedge to push the accordion structures 508 away along the fold direction. Thus, this wedge (third component) 506 increases the outward push to increase the surface-to-surface contact of the arced surface area portions 514 to the inner wall surface(s) of the inner chamber of the ampoule. The wedge (third component) 506 is also configured to create a vent(s) or at least one passageway(s) 516 for fluid flow (e.g., flow of gas) when the tray 500 is installed within an ampoule. The tray 500 is also configured to be stackable with other trays of same or similar structure. The maximum(s) of one tray 500 can contact and/or connect to the minimum(s) of another tray when stacking a plurality of these trays 500.

While the tray 200 shown in FIG. 2A has one compartment per plate, the tray 300 shown in FIGS. 3A and 3B has two compartments, and the tray 400 shown in FIG. 4A has four compartments, it will be understood that any number of compartments can be formed by varying some of the structures of the embodiments of the modular trays. In some embodiments, the compartments are divided compartments. Accordingly, such trays are within the scope of this disclosure. Accordingly, in some embodiments of the modular tray, there is at least one compartment. In some embodiments of the modular tray, there are at least two compartments. In some embodiments of the modular tray, there are at least three compartments. In some embodiments of the modular tray, there are at least four compartments. In some embodiments of the modular tray, there are at least five compartments. In some embodiments of the modular tray, there are at least six compartments. In some embodiments of the modular tray, there are at least seven compartments. In some embodiments of the modular tray, there are at least eight compartments. In some embodiments of the modular tray, there are at least nine compartments. In some embodiments of the modular tray, there are at least ten compartments. In some embodiments of the modular tray, there are at least eleven compartments. In some embodiments of the modular tray, there are at least twelve compartments. In some embodiments of the modular tray, there are at least thirteen compartments. In some embodiments of the modular tray, there are at least fourteen compartments. In some embodiments of the modular tray, there are at least fifteen compartments. In some embodiments of the modular tray, there are at least sixteen compartments. In some embodiments of the modular tray, there are at least seventeen compartments. In some embodiments of the modular tray, there are at least eighteen compartments. In some embodiments of the modular tray, there are at least nineteen compartments. In some embodiments of the modular tray, there are at least twenty compartments.

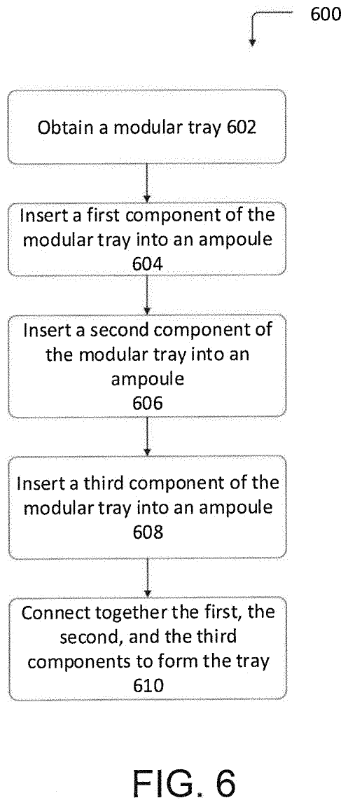

FIG. 6 shows an exemplary flowchart according to some of the embodiments of the methods for inserting a modular tray into an ampoule. The modular tray can be any of the embodiments as described herein. The method 600 includes obtaining 602 a modular tray according to any of the embodiments described herein. Then, inserting 604 a first component of the modular tray into an inner chamber of the ampoule. The method 600 includes inserting 606 a second component of the modular tray into the inner chamber of the ampoule. The method 600 includes inserting 608 a third component of the modular tray into the inner chamber of the ampoule. Then, connecting 610 the first, the second, and the third components to form the assembled modular tray, which can then lead to an expansion of or a configuration of the assembled modular tray to fit snugly and tightly to the inner wall surface of the inner chamber.

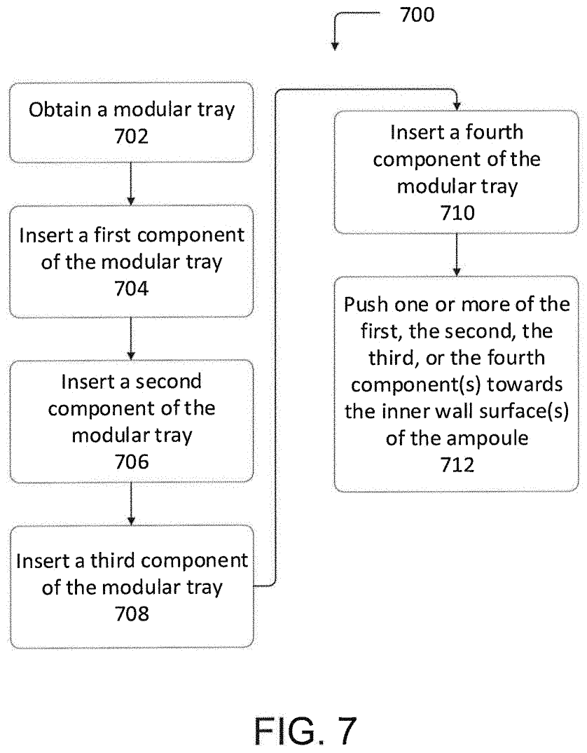

FIG. 7 shows an exemplary flowchart according to some of the embodiments of the methods for inserting a modular tray into an ampoule. The modular tray can be any of the embodiments as described herein. The method 700 includes obtaining 702 a modular tray according to any of the embodiments described herein. Then, inserting 704 a first component of the modular tray into an inner chamber of the ampoule. The method 700 includes inserting 706 a second component of the modular tray into the inner chamber of the ampoule. The method 700 includes inserting 708 a third component of the modular tray into the inner chamber of the ampoule. Then, the method 700 includes inserting 710 a fourth component of the modular tray into the inner chamber of the ampoule. Then, pushing 712 at least one of the first, the second, the third, or the fourth component(s) towards the inner wall surface(s) of the inner chamber of the ampoule.

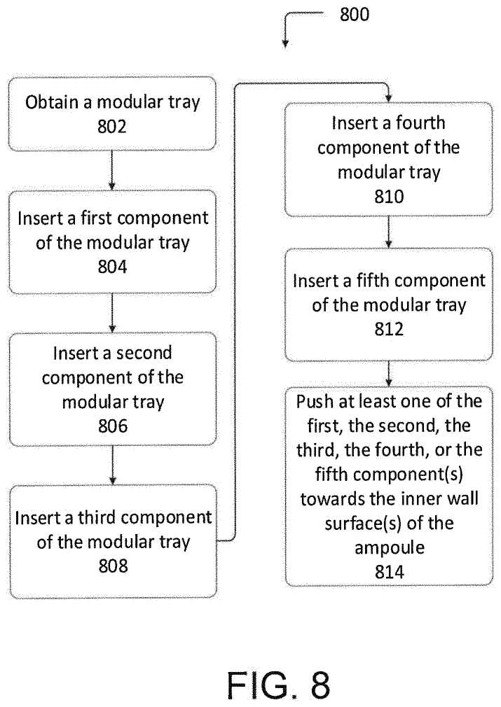

FIG. 8 shows an exemplary flowchart according to some of the embodiments of the methods for inserting a modular tray into an ampoule. The modular tray can be any of the embodiments as described herein. The method 800 includes obtaining 802 a modular tray according to any of the embodiments described herein. Then, inserting 804 a first component of the modular tray into an inner chamber of the ampoule. The method 800 includes inserting 806 a second component of the modular tray into the inner chamber of the ampoule. The method 800 includes inserting 808 a third component of the modular tray into the inner chamber of the ampoule. Then, the method 800 includes inserting 810 a fourth component of the modular tray into the inner chamber of the ampoule. The method 800 further includes inserting 812 a fifth component of the modular tray into the inner chamber of the ampoule. Then, pushing 814 at least one of the first, the second, the third, the fourth, or the fifth component(s) towards the inner wall surface(s) of the inner chamber of the ampoule.

The terminology used herein is intended to describe embodiments and is not intended to be limiting. The terms “a,” “an,” and “the” include the plural forms as well, unless clearly indicated otherwise. The terms “comprises” and/or “comprising,” when used in this Specification, specify the presence of the stated features, integers, steps, operations, elements, and/or components, but do not preclude the presence or addition of one or more other features, integers, steps, operations, elements, and/or components.

It is to be understood that any of the embodiments or any portion(s) thereof may be combined with any of the other embodiments without departing from the scope of the present disclosure. It is also to be understood that changes may be made in detail, especially in matters of the construction materials employed and the shape, size, and arrangement of parts without departing from the scope of the present disclosure. This Specification and the embodiments described are examples, with the true scope and spirit of the disclosure being indicated by the claims that follow.

What is claimed is:

1. A modular tray for an ampoule, comprising:
a first component;
a second component; and
a third component,
wherein the first component, the second component, and the third component are configured to be disengageably connectable together, such
the second component is in thermal contact with the first component, and
the third component is in thermal contact with the first component and the second component.

2. The modular tray of claim 1, wherein
the first component includes a top plate;
the second component includes a wedge; and
the third component includes a bottom plate,
wherein the second component is disposed between the first component and the third component.

3. The modular tray of claim 1, further comprising:
a bottom plate,
wherein the bottom plate is configured to hold solid precursor materials,
wherein the bottom plate is configured to be disengageably connectable to at least one of the first component, the second component, or the third component, such that when connected, the bottom plate is in thermal contact with at least one of the first component, the second component, or the third component.

4. The modular tray of claim 3, wherein
the first component includes a first wall having a first arced portion;
the second component includes a second wall having a second arced portion; and
the third component includes a wedge portion,
wherein the wedge portion is configured to be disengageably connect to the first arced portion to define a first divided compartment.

5. The modular tray of claim 4, wherein the wedge portion is configured to push the first arced portion towards an inner wall surface of the ampoule for enhancing a thermal energy transfer from the inner wall surface to the solid precursor materials.

6. The modular tray of claim 4, wherein the wedge portion is configured to be disengageably connect to the second arced portion to define a second divided compartment.

7. The modular tray of claim 6, wherein the wedge portion is configured to push the second arced portion towards an inner wall surface of the ampoule for enhancing a thermal energy transfer from the inner wall surface to the solid precursor materials.

8. The modular tray of claim 1, wherein the first component comprises:
a bottom plate portion; and
an arced wall portion,
wherein the bottom plate portion is configured to be in thermal contact with the arced wall portion.

9. The modular tray of claim 8, wherein the first component comprises:
a first wall portion,
wherein the first wall portion is in thermal contact with the bottom plate portion and the arced wall portion; and
a second wall portion,
wherein the second wall portion is in thermal contact with the bottom plate portion, the arced wall portion, and the first wall portion.

10. The modular tray of claim 9, wherein the first component defines a first divided compartment.

11. The modular tray of claim 10,
wherein the second component defines a second divided compartment.

12. The modular tray of claim 11,
wherein the third component defines a third divided compartment.

13. The modular tray of claim 12, further comprising:
a fourth component,
wherein the fourth component defines a fourth divided compartment,
wherein the fourth component is configured to be disengageably connect to at least one of the first compartment, the second component, the third component, or any thereof,
such that when connected, the fourth component is in thermal contact with at least one of the first component, the second component, the third component, or any thereof.

14. The modular tray of claim 13,
wherein any one or more of the first component, the second component, the third component, or the fourth component have substantially similar structures.

15. The modular tray of claim 13,
wherein the first component and the second component connect together to define a flow path for a carrier gas.

16. The modular tray of claim 13,
wherein the second component and the third component connect together to define a flow path for a carrier gas.

17. The modular tray of claim 13,
wherein the third component and the fourth component connect together to define a flow path for a carrier gas.

18. An ampoule, comprising:
the modular tray according to claim 1.

19. A method of inserting a modular tray into an ampoule, comprising:
obtaining the modular tray according to claim 1;
inserting the first component into an inner volume of the ampoule;
inserting the second component into the inner volume of the ampoule;
inserting the third component into the inner volume of the ampoule; and
connecting together the first component, the second component, and the third component.

20. The method of claim 19, further comprising:
inserting the fourth component into the inner volume of the ampoule; and
connecting the fourth component with the first component, the second component, and the third component.
